(19) United States
(12) Patent Application Publication
(10) Pub. No.: US 2009/0082240 A1
(43) Pub. Date: Mar. 26, 2009

(54) STRIPPING LIQUID FOR SEMICONDUCTOR DEVICE, AND STRIPPING METHOD

(75) Inventors: Katsuyuki NUKUI, Shizuoka (JP); Hiroyuki Seki, Shizuoka (JP); Tadashi Inaba, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/210,721

(22) Filed: Sep. 15, 2008

(30) Foreign Application Priority Data
Sep. 20, 2007 (JP) 2007-243289

(51) Int. Cl. G03F 7/42

(52) U.S. Cl. 510/176

(57) ABSTRACT

A stripping liquid for a semiconductor device is provided that includes an aqueous solution containing a quaternary ammonium hydroxide, an oxidizing agent, an alkanolamine, and an alkali metal hydroxide. There is also provided a stripping method that includes a stripping liquid preparation step of preparing the stripping liquid and a stripping step of removing at least one deposit selected from the group consisting of a photoresist, an anti-reflection film, and an etching residue by means of the stripping liquid obtained in the stripping liquid preparation step.

### BACKGROUND OF THE INVENTION

1. Field of the Invention

The present invention relates to a stripping liquid for a semiconductor device, and a stripping method. More particularly, the present invention relates to a process for producing a semiconductor device, and it relates to a method for stripping a photoresist, an anti-reflection film, and an etching residue present on a substrate in a front end step, particularly for a semiconductor device, and to a stripping liquid for removing a photoresist, an anti-reflection film, and an etching residue.

2. Description of the Related Art

In the production of semiconductor devices in recent years, in order to achieve higher wiring density, an organosiloxane-based compound has been used in an anti-reflection film in a photolithography process. By providing the organosiloxane-based compound as an anti-reflection film in a lower layer of a photoresist film, light scattering on the undersurface of the photoresist film caused when the photoresist is subjected to pattern exposure can be prevented and the pattern shape can be protected during dry etching. In the semiconductor device production process, after dry etching it is necessary to remove the photoresist film, anti-reflection film, and etching residue formed during etching.

Conventionally, in the semiconductor device production process, tungsten, aluminum, copper, tantalum, nickel, cobalt, a metal nitride, an alloy, etc. of these metals are used as wiring metals and barrier metals, and recently new attempts have been made to use titanium or titanium nitride as barrier metal or a metal hardmask. In the semiconductor device production process, these metals contained in semiconductor devices are frequently required not to corrode.

JP-A-62-49355 (JP-A denotes a Japanese unexamined patent application publication) discloses a stripping agent composition for stripping a photoresist film formed on an inorganic substrate, the stripping agent composition comprising (a) 10 to 50 wt % of an alkanolamine represented by the formula H₃₋ₙN((CH₂)ₘOH)ₙ (m denotes a numeral of 2 or 3 and n denotes a numeral of 1, 2, or 3) or an ethylene oxide adduct of a polyalkylene polyamine represented by the formula H₂N((CH₂)ₓNH)_{y}H (x denotes a numeral of 2 or 3 and y denotes a numeral of 2, 3, or 4), (b) 1 to 20 wt % of a sulfone compound represented by the formula R¹—SO₂—R² (R¹ and R² independently denote an alkyl group having 1 or 2 carbons or are bonded to each other to form cyclic alkylene group having 4 or 5 carbons), and (c) 30 to 89 wt % of a glycol monoalkyl ether represented by the formula HO—(C₂H₄O)ₚ—R (R denotes an alkyl group having 1 to 5 carbons and p denotes a numeral of 1, 2, or 3).

JP-A-64-42653 discloses a stripping liquid for a positive photoresist, the stripping liquid comprising (A) dimethylsulfoxide as a main component, (B) 1 to 50 wt % of at least one type of solvent selected from a diethylene glycol monoalkyl ether, a diethylene glycol dialkyl ether, γ-butyrolactone, and 1,3-dimethyl-2-imidazolidinone, and (C) 0.1 to 5 wt % of a nitrogen-containing organic hydroxyl compound solvent.

JP-A-4-289866 discloses a composition for removing a corrosion resistant film from a support, the composition comprising hydroxylamine and at least one alkanolamine that is miscible with the hydroxylamine, the hydroxylamine and the alkanolamine being present in an amount sufficient to remove a corrosion resistant film from a support.

U.S. Pat. No. 5,185,235 discloses a photoresist stripping liquid comprising a mixture of (A) 35 to 80 wt % of an aliphatic alcohol solvent selected from the group consisting of methanol, ethanol, propanol, 3-methyl-3-methoxybutyl alcohol, ethylene glycol monomethyl ether, ethylene glycol monoethyl ether, ethylene glycol monobutyl ether, diethylene glycol monomethyl ether, diethylene glycol monoethyl ether, propylene glycol monomethyl ether, and dipropylene glycol monomethyl ether, (B) 10 to 50 wt % of an organic solvent selected from the group consisting of halogenated hydrocarbon solvents, non-halogenated ether solvents selected from the group consisting of dioxane, tetrahydrofuran, diethylene glycol dimethyl ether, triethylene glycol dimethyl ether, tetraethylene glycol dimethyl ether, ethylene glycol diethyl ether, diethylene glycol diethyl ether, and diethylene glycol dibutyl ether, and non-halogenated aromatic solvents, and (C) 0.1 to 25 wt % of a quaternary ammonium salt.

JP-A-7-297158 discloses an alkaline washing liquid for a microelectronic substrate, the washing liquid comprising an aqueous solution of a non-metal ion base, a nonionic surfactant, and an effective amount of a pH-reducing chemical component for reducing or adjusting the pH of the washing liquid to a range of about 8 to about 10.

JP-A-2007-119783 discloses a washing liquid comprising 0.01 to 10 wt % of potassium hydroxide and/or sodium hydroxide, 5 to 80 wt % of a water-soluble organic solvent, 0.0001 to 10 wt % of a group 9 metal, group 9 metal alloy, or group 11 metal corrosion inhibitor, and water.

### BRIEF SUMMARY OF THE INVENTION

When the conventional stripping liquids are applied to a semiconductor device containing titanium or titanium nitride, any of the problems of titanium or titanium nitride corroding, removal of a photoresist or an etching residue being insufficient even though titanium and titanium nitride do not corrode, the time required for a stripping process being too long, etc. occur. As a result of an investigation by the present inventors, it has been found that it is very difficult for the conventional stripping liquids to make titanium or titanium nitride remain while at the same time removing a photoresist, an anti-reflection film (an organosiloxane-based anti-reflection film in particular), and an etching residue.

It is an object of the present invention to provide a stripping liquid that can remove at least one deposit selected from the group consisting of a photoresist, an anti-reflection film, and an etching residue at a low temperature in a short period of time without corroding a metal, a metal nitride, an alloy, or an interlayer insulating film of a stripping target, and a stripping method therefor.

The object of the present invention has been attained by the following means.
(1) A stripping liquid for a semiconductor device, the stripping liquid comprising an aqueous solution comprising a quaternary ammonium hydroxide, an oxidizing agent, an alkanolamine, and an alkali metal hydroxide,
(2) the stripping liquid according to (1), wherein the quaternary ammonium hydroxide is at least one compound selected from the group consisting of tetramethylammonium hydroxide, tetraethylammonium hydroxide, trimethylhydroxyethylammonium hydroxide, methyltri(hydroxyethyl)ammonium hydroxide, and tetra(hydroxyethyl)ammonium hydroxide,
(3) the stripping liquid according to (1) or (2), wherein the oxidizing agent is at least one compound selected from the group consisting of hydrogen peroxide, nitric acid and salts thereof, and ammonium persulfate, periodate, perbromate, perchlorate, iodate, bromate, and chlorate,
(4) the stripping liquid according to any one of (1) to (3), wherein the alkanolamine is represented by Formula (1)

R¹₃₋ₙN(CₘH₂ₘ(OH))ₙ (1)

(in Formula (1), R¹ denotes a hydrogen atom or an alkyl group having 1 to 4 carbons, m denotes an integer of 2 to 4, and n denotes an integer of 1 to 3),
(5) the stripping liquid according to any one of (1) to (4), wherein the alkali metal hydroxide is at least one compound selected from the group consisting of lithium hydroxide, sodium hydroxide, potassium hydroxide, rubidium hydroxide, and cesium hydroxide,
(6) the stripping liquid according to any one of (1) to (5), wherein it has a pH of 7 to 15,
(7) a stripping method comprising a stripping liquid preparation step of preparing the stripping liquid according to any one of (1) to (6) above, and a stripping step of removing at least one deposit selected from the group consisting of a photoresist, an anti-reflection film, and an etching residue by means of the stripping liquid obtained in the stripping liquid preparation step, and
(8) the stripping method according to (7), wherein the anti-reflection film is an organosiloxane-based compound.

### DETAILED DESCRIPTION OF THE INVENTION

In recent years, shortening the stripping time in a semiconductor device production process has become an important issue in stripping technology. Conventionally, as a liquid for removing a photoresist, an anti-reflection film, and an etching residue, for example, there are a stripping liquid comprising a mixed system of an alkanolamine and an organic solvent (ref. JP-A-62-49355 and JP-A-64-42653) and a stripping liquid comprising an alkanolamine, a hydroxylamine, catechol, and water (ref. JP-A-4-289866), but these stripping liquids do not have sufficient ability to remove an organosiloxane-based anti-reflection film and, in addition, corrode copper and Ti, and are not suitable as a stripping liquid for the stripping target of the present invention. Furthermore, in the case of a stripping liquid employing an organic quaternary ammonium salt (U.S. Pat. No. 5,185,235), corrosion of copper and Ti is suppressed, but the ability to remove a photoresist and an organosiloxane-based anti-reflection film is not sufficient. Moreover, a stripping liquid comprising water, tetramethylammonium hydroxide, hydrogen peroxide, and a nonionic surfactant (JP-A-7-297158) requires a high temperature and a sufficiently long period of time for removal of a photoresist and an organosiloxane-based anti-reflection film, and it is not satisfactory for device production aiming for high throughput. Furthermore, a stripping liquid comprising sodium hydroxide or potassium hydroxide, a water-soluble organic solvent, and a group 9 or group 11 metal corrosion inhibitor (JP-A-2007-119783) can perform stripping in a relatively short period of time, but it cannot be said that the temperature is sufficiently low or the time is sufficiently short and, moreover, a benzotriazole used as the corrosion inhibitor imposes a high environmental burden, and it is desirable that the use thereof in device production is avoided if possible.

The stripping liquid for a semiconductor device of the present invention (hereinafter, also simply called a ‘stripping liquid’) comprises an aqueous solution comprising a quaternary ammonium hydroxide, an oxidizing agent, an alkanolamine, and an alkali metal hydroxide. The stripping liquid of the present invention is preferably used in a semiconductor device production process, and preferably in a front end step of semiconductor device production, for the removal of at least one deposit selected from the group consisting of a photoresist, an anti-reflection film, and an etching residue deposited on the surface of a stripping target such as a semiconductor device, and more preferably for the removal of all photoresist, anti-reflection film, and etching residue deposits. The etching residue referred to in the present invention means a by-product formed by carrying out etching, including a photoresist-derived organic residue, an Si-containing residue, and a metal-containing residue.

The present invention is explained in detail below.

### Quaternary Ammonium Hydroxide

The stripping liquid of the present invention comprises a quaternary ammonium hydroxide.

The quaternary ammonium hydroxide is preferably at least one quaternary ammonium hydroxide selected from the group consisting of tetramethylammonium hydroxide, tetraethylammonium hydroxide, trimethylhydroxyethylammonium hydroxide, methyltri(hydroxyethyl)ammonium hydroxide, and tetra(hydroxyethyl)ammonium hydroxide, and among them it is more preferable in the present invention to use tetramethylammonium hydroxide or tetraethylammonium hydroxide. The quaternary ammonium hydroxide may be used on its own or in a combination of two or more types.

The content of the quaternary ammonium hydroxide, relative to the total weight of the stripping liquid, is preferably 0.01 to 50 wt % (in the present invention, unless otherwise specified, ‘at least 0.01 wt % but no greater than 50 wt %’ is also referred to as ‘0.01 to 50 wt %’, this applies to descriptions of ranges for other values), more preferably 1 to 45 wt %, and yet more preferably 5 to 40 wt %. When the content of the quaternary ammonium hydroxide is in the above range of values, corrosion of an interlayer insulating film comprising SiOC as a main component or of a silicon substrate can be suppressed or reduced.

### Oxidizing Agent

The stripping liquid of the present invention comprises an oxidizing agent.

The oxidizing agent here is preferably at least one oxidizing agent selected from the group consisting of hydrogen peroxide, nitric acid and salts thereof, and ammonium persulfate, periodate, perbromate, perchlorate, iodate, bromate, and chlorate, and among them it is more preferable to use hydrogen peroxide or nitric acid. The oxidizing agent may be used on its own or in a combination of two or more types.

The content of the oxidizing agent, relative to the total weight of the stripping liquid, is preferably 0.01 to 20 wt %, more preferably 0.1 to 10 wt %, and yet more preferably 2 to 7 wt %. When the content of the oxidizing agent is in the above range of values, the pH of the stripping liquid is appropriate, and a photoresist, an anti-reflection film, and an etching residue can be removed sufficiently.

### Alkanolamine

The stripping liquid of the present invention comprises an alkanolamine.

The alkanolamine is preferably an alkanolamine represented by Formula (1).

R¹₃₋ₙN(CₘH₂ₘ(OH))ₙ (1)

(In Formula (1), R¹ denotes a hydrogen atom or an alkyl group having 1 to 4 carbons, m denotes an integer of 2 to 4, and n denotes an integer of 1 to 3.)

Specific examples thereof include monoethanolamine, diethanolamine, triethanolamine, propanolamine, dipropanolamine, tripropanolamine, isopropanolamine, diisopropanolamine, triisopropanolamine, butanolamine, N-methylethanolamine, N-methyldiethanolamine, N,N-dimethylaminoethanol, N-ethylethanolamine, N-ethyldiethanolamine, N,N-diethylethanolamine, N-n-butylethanolamine, N,N-di-n-butylethanolamine, and at least one type of salt thereof, and among them it is preferable to use monoethanolamine, diethanolamine, or triethanolamine. The alkanolamine may be used on its own or in a combination of two or more types.

The content of the alkanolamine, relative to the total weight of the stripping liquid, is preferably 0.01 to 50 wt %, more preferably 1 to 45 wt %, and yet more preferably 10 to 40 wt %. When the content of the alkanolamine is in the above range of values, corrosion of an interlayer insulating film comprising SiOC as a main component or of a silicon substrate can be suppressed or reduced.

### Alkali Metal Hydroxide

The stripping liquid of the present invention comprises an alkali metal hydroxide formed from pairing of an alkali metal element and a hydroxy group. The alkali metal hydroxide here is preferably at least one alkali metal hydroxide selected from the group consisting of lithium hydroxide, sodium hydroxide, potassium hydroxide, rubidium hydroxide, and cesium hydroxide, and in the present invention it is more preferable to use sodium hydroxide, potassium hydroxide, or cesium hydroxide. The alkali metal hydroxide or a hydrate thereof may be used on its own or in a combination of two or more types.

The content of the alkali metal hydroxide, relative to the total weight of the stripping liquid, is preferably 0.01 to 10 wt %, and more preferably 0.01 to 5 wt %. When the content of the alkali metal hydroxide is in the above range of values, corrosion of an interlayer insulating film comprising SiOC as a main component or of a silicon substrate can be suppressed or reduced.

### Water

The stripping liquid of the present invention comprises water, and the content of water, relative to the total weight of the stripping liquid, is 0.01 to 80 wt %, and preferably 0.01 to 60 wt %. When the water content is in the above range of values, the concentrations of other components among the stripping liquid components are appropriate, and a photoresist, an anti-reflection film, and an etching residue can be removed sufficiently.

### Stripping Target

In the present invention, the material of a semiconductor device that is a stripping target is, for example, silicon, amorphous silicon, polysilicon, silicon oxide, silicon nitride, a semiconductor substrate to which has been applied a semiconductor wiring material such as copper, titanium, titanium-tungsten, titanium nitride, tungsten, tantalum, a tantalum compound, chromium, chromium oxide, or aluminum, or a compound semiconductor such as gallium-arsenic, gallium-phosphorus, or indium-phosphorus, a printed board such as a polyimide resin, or a glass substrate used in an LCD. The stripping liquid of the present invention does not corrode these materials.

The pH of the stripping liquid of the present invention is preferably 7 to 15, more preferably 10 to 14, and yet more preferably 11 to 14. When the pH is in the above range of values, a photoresist, an anti-reflection film, and an etching residue can be removed sufficiently.

The stripping liquid of the present invention optionally comprises a water-soluble organic solvent, a corrosion inhibitor, a fluorine-containing compound, or a surfactant, thus giving yet more preferred performance.

### Water-Soluble Organic Solvent

The stripping liquid of the present invention may comprise a water-soluble organic solvent. Examples of the water-soluble organic solvent include alcohol-based solvents such as methyl alcohol, ethyl alcohol, 1-propyl alcohol, 2-propyl alcohol, ethylene glycol, propylene glycol, glycerol, 1,6-hexanediol, neopentyl glycol, trimethylolpropane, 1,2,4-butanediol, 1,2,6-hexanetriol, sorbitol, and xylitol, ether-based solvents such as ethylene glycol monomethyl ether, ethylene glycol monoethyl ether, ethylene glycol monobutyl ether, diethylene glycol, diethylene glycol monomethyl ether, diethylene glycol monoethyl ether, diethylene glycol monobutyl ether, triethylene glycol, tetraethylene glycol, polyethylene glycol, propylene glycol monomethyl ether, propylene glycol monoethyl ether, propylene glycol monobutyl ether, dipropylene glycol monomethyl ether, dipropylene glycol monoethyl ether, dipropylene glycol monobutyl ether, diethylene glycol dimethyl ether, dipropylene glycol dimethyl ether, and 3-methyl-3-methoxybutanol, amide-based solvents such as formamide, monomethylformamide, dimethylformamide, monoethylformamide, diethylformamide, acetamide, monomethylacetamide, dimethylacetamide, monoethylacetamide, diethylacetamide, N-methylpyrrolidone, and N-ethylpyrrolidone, sulfur-containing solvents such as dimethylsulfone, dimethylsulfoxide, and sulfolane, imidazolidinone-based solvents such as 1,3-dimethyl-2-imidazolidinone, 1,3-diethyl-2-imidazolidinone, and 1,3-diisopropyl-2-imidazolidinone, and lactone-based solvents such as y-butyrolactone and 6-valerolactone. Among them, the alcohol-based, ether-based, amide-based, and sulfur-containing solvents are preferable, and 1,6-hexanediol, tetraethylene glycol, propylene glycol, dipropylene glycol monomethyl ether, N-methylpyrrolidone, and dimethylsulfoxide are more preferable. The water-soluble organic solvent may be used on its own or in a combination of two or more types as appropriate.

The water-soluble organic solvent is preferably used at a concentration of 0 to 40 wt % relative to the total weight of the stripping liquid, and more preferably at a concentration of 0 to 20 wt %. Adding the water-soluble organic solvent to the stripping liquid enables the removal of an etching residue to be promoted.

### Corrosion Inhibitor

The stripping liquid of the present invention may comprise a corrosion inhibitor.

Examples of the corrosion inhibitor include carboxylic acids such as formic acid, acetic acid, glyoxylic acid, propionic acid, valeric acid, isovaleric acid, oxalic acid, malonic acid, succinic acid (butanedioic acid), glutaric acid, maleic acid, fumaric acid, phthalic acid, 1,2,3-benzenetricarboxylic acid, glycolic acid, lactic acid (2-hydroxypropionic acid), citric acid, salicylic acid, tartaric acid, and gluconic acid, catechols (which may have one or more substituent having C1 to C6) such as alkylcatechols such as methylcatechol, ethylcatechol, and tert-butylcatechol, benzotriazoles such as benzotriazol and alkyl benzotriazol, hydroxyanisoles (which may have one or more substituent having C1 to C10) such as butyl hydroxyanisole, gallic acid, gallic acid esters such as methyl gallate and propyl gallate, and tetra alkylammonium silicates (which may have one or more substituent having C1 to C6) such as tetramethylammonium silicate. In general, such corrosion inhibitors are commercially available from various sources (e.g. Aldrich, etc.), and may be used without further purification.

The corrosion inhibitor is preferably used at a concentration of 0 to 10 wt % relative to the total weight of the stripping liquid. Adding the corrosion inhibitor to the stripping liquid enables the reduction potential of the stripping liquid to be adjusted, thereby preventing corrosion of a metal, a metal nitride, or an alloy thereof contained in a device.

### Fluorine-Containing Compound

The stripping liquid of the present invention may comprise a fluorine-containing compound.

The fluorine-containing compound is a fluoride salt formed by a reaction between hydrofluoric acid and ammonia or an organic amine. Examples thereof include ammonium fluoride, ammonium hydrogen fluoride, methylamine hydrofluoride, ethylamine hydrofluoride, propylamine hydrofluoride, tetramethylammonium fluoride, tetraethylammonium fluoride, ethanolamine hydrofluoride, and triethylenediamine hydrofluoride.

The fluorine-containing compound is preferably used at a concentration of 0 to 10 wt % relative to the total weight of the stripping liquid. Adding the fluorine-containing compound to the stripping liquid enables the removal of a photoresist, an anti-reflection film, and an etching residue to be promoted.

### Surfactant

The stripping liquid of the present invention may comprise a surfactant. As the surfactant, a nonionic, anionic, or cationic surfactant may be used. Such surfactants are generally commercially available.

The surfactant is preferably 0 to 5 wt % relative to the total weight of the stripping liquid. Adding the surfactant to the stripping liquid enables the viscosity of the stripping liquid to be adjusted, thereby improving the wettability toward a stripping target.

### Stripping Method

The stripping method of the present invention comprises a stripping liquid preparation step of preparing the stripping liquid of the present invention and a stripping step of removing a photoresist, an anti-reflection film, or an etching residue (hereinafter, also called a ‘photoresist, etc.’) by means of the stripping liquid obtained in the stripping liquid preparation step.

The stripping method of the present invention is explained in detail below.

The stripping step may be carried out by any known method. As a method in which a stripping liquid and a photoresist, etc. to be stripped are contacted, specific examples thereof include an immersion method, a spraying method, and a method involving a sheet feed system.

The temperature of the stripping liquid when carrying out the stripping method of the present invention is preferably in the range of 15° C. to 100° C., more preferably 15° C. to 80° C., and yet more preferably 20° C. to 50° C. The temperature range depends on the method used, but may be selected as appropriate according to etching conditions and the stripping target used.

The time for which the stripping liquid of the present invention and the photoresist, etc. are contacted is preferably 1 to 30 minutes, more preferably 1 to 10 minutes, and yet more preferably 1 to 5 minutes. It is preferable for it to be in the above-mentioned range of values since a photoresist, an anti-reflection film, or an etching residue can be removed sufficiently, and the time required for the stripping method is short.

In the stripping method of the present invention, it is also preferable to carry out stripping of a photoresist, etc. by repeating the stripping step with the stripping liquid two or more times. It is preferable to repeat the stripping step two or more times since the performance in removing a photoresist, etc. is improved. The stripping step may be repeated any number of times until a photoresist, etc. is completely removed, but it is preferably repeated 1 to 3 times, and more preferably 1 to 2 times.

The stripping method of the present invention may employ ultrasonic waves in combination as necessary in the stripping step.

When rinsing after a photoresist, an etching residue thereof, etc. on a stripping target is removed, it is unnecessary to use an alcohol-based organic solvent such as isopropanol, and residual stripping liquid may be removed from the surface of the stripping target merely by rinsing with water. When stripping a photoresist that is in a state of advanced deterioration due to etching, a pretreatment with a hydrogen peroxide-containing solution is effective.

In accordance with the present invention, without corroding a metal, a metal nitride, an alloy, or an interlayer insulating film material contained in a stripping target, it becomes possible to carry out, in a low temperature environment in a short period of time, the removal of at least one deposit selected from the group consisting of a deposit on the surface of the stripping target such as a photoresist or an etching residue after dry etching, and an anti-reflection film (an organosiloxane-based anti-reflection film or a shape protection film).

### EXAMPLES

The present invention is more specifically explained by reference to Examples. The present invention should not be construed as being limited by these Examples.

Films were formed on a silicon substrate in the sequence copper, SiOC-based interlayer insulating film (Low-k film), metal hardmask (Ti or TiN), anti-reflection film (organosiloxane-based), and photoresist, dry etching was carried out using exposed and developed photoresist as a mask to thus form via holes, and a patterned wafer in which the copper, interlayer insulating film, metal hardmask, anti-reflection film, and photoresist were exposed on an inner wall face of the via holes was obtained.

When a cross section of this patterned wafer was examined by a scanning electron microscope (SEM), there was etching residue on the wall face of the via hole.

### Examples 1 to 6 and Comparative Examples 1 to 10

Subsequently, stripping liquids 1 to 15 having the compositions shown in Table 1 were prepared, a segment (2 cm×2 cm) from the patterned wafer was immersed in each of the solutions temperature-controlled as described in Table 1, and the segment of patterned wafer was taken out after the immersion time described in Table 1, immediately washed with DI water, and N₂-dried. A cross section and the surface of the segment of patterned wafer after the immersion test were examined by SEM, and the removability of the photoresist, the organosiloxane-based anti-reflection film, and the etching residue, and the corrosion of copper, Ti, TiN, the silicon substrate, and the SiOC-based interlayer insulating film were evaluated in accordance with the evaluation criteria below. The immersion test was carried out at an immersion temperature of 20° C. to 80° C. for an immersion time of 1 minute to 30 minutes, and results of evaluation of removability and corrosion are summarized in Table 1.

The evaluation criteria are given below.

### Removability

A: Photoresist, anti-reflection film, etching residue completely removed.
B: Undissolved photoresist, anti-reflection film, etching residue remained.
C: Hardly any photoresist, anti-reflection film, etching residue removed.

### Corrosion

A: No corrosion in copper, Ti, TiN, silicon substrate, SiOC-based interlayer insulating film.
B: Slight degree of corrosion observed in at least one material among copper, Ti, TiN, silicon substrate, and SiOC-based interlayer insulating film.
C: High degree of corrosion was observed in at least one material among copper, Ti, TiN, silicon substrate, and SiOC-based interlayer insulating film.

In the evaluation above, it is desirable that both the removability and the corrosion give an A. It is more desirable that an evaluation of A is given for a test at a low temperature for a short period of time.

As shown in Table 1, in Examples 1 to 6, in which the stripping liquid and the stripping method of the present invention were applied, there was no corrosion of copper, Ti, TiN, the silicon substrate, or the SiOC-based interlayer insulating film, and the removability of the photoresist, the organosiloxane-based anti-reflection film, and the etching residue was excellent. In stripping using the stripping liquid of the present invention, the immersion temperature and the immersion time can be selected relatively freely, stripping is possible at a low temperature in a short period of time, and there is no corrosion of copper, Ti, TiN, the silicon substrate, or the SiOC-based interlayer insulating film even under forcing conditions in which the immersion time is increased. In Comparative Examples 1 to 10, even by adjusting the immersion time and immersion temperature, none thereof gave sufficient removability and a satisfactory level of corrosion.

TABLE 1

| | | | Example/Comparative Example | | | | | | | | | |
|---|---|---|---|---|---|---|---|---|---|---|---|---|
| | | | Example | | | | | | Comparative Example | | | |
| | | | 1 | 2 | 3 | 4 | 5 | 6 | 1 | 2 | 3 | 4 |
| Solution No. | | | 1 | 2 | 3 | 4 | 5 | 3 | 6 | 7 | 8 | 9 |
| Composition | Quaternary ammonium | Tetramethylammonium | — | 12 | — | 15 | 40 | — | 25 | 60 | — | 15 |
| (wt %) | hydroxide | hydroxide | | | | | | | | | | |
| | | Tetraethylammonium | 15 | — | 15 | 5 | — | 15 | — | — | — | — |
| | | hydroxide | | | | | | | | | | |
| | Oxidizing agent | Hydrogen peroxide | 7 | 5 | — | 2 | 2 | — | — | — | 5 | 22 |
| | | Nitric acid | — | — | 6 | — | 2 | 6 | 40 | 5 | — | — |
| | Alkali metal hydroxide | Sodium hydroxide | — | — | 5 | — | 4 | 5 | — | — | 6 | — |
| | | Potassium hydroxide | — | 2 | — | 3 | 2 | — | — | 4 | — | — |
| | | Cesium hydroxide | 3 | — | — | — | — | — | 6 | — | — | 8 |
| | Alkanolamine | Monoethanolamine | 30 | — | 20 | 10 | — | 20 | — | 15 | 30 | — |
| | | Triethanolamine | — | 35 | — | 10 | 40 | — | 10 | — | — | 15 |
| | Water | | 45 | 46 | 54 | 41.9 | 10 | 54 | 19 | 16 | 59 | 40 |
| | Water-soluble organic | Dimethylsulfoxide | — | — | — | 10 | — | — | — | — | — | — |
| | solvent | | | | | | | | | | | |
| | Corrosion inhibitor | 1,2,3,-Benzotriazole | — | — | — | 0.01 | — | — | — | — | — | — |
| | Corrosion inhibitor | Catechol | — | — | — | 0.1 | — | — | — | — | — | — |
| | Fluorine-containing | Ammonium fluoride | — | — | — | 3 | — | — | — | — | — | — |
| | compound | | | | | | | | | | | |
| | Surfactant | Sodium | — | — | — | 0.005 | — | — | — | — | — | — |
| | | dodecylbenzenesulfonate | | | | | | | | | | |

| | | | | | | | | | | | |
|---|---|---|---|---|---|---|---|---|---|---|---|
| Treatment | pH | 13.6 | 13.1 | 12.8 | 12.5 | 11.8 | 12.8 | 6.3 | 12.1 | 10.8 | 8.2 |
| conditions | Temperature [° C.] | 40 | 30 | 20 | 20 | 20 | 20 | 50 | 20 | 30 | 80 |
| | Time [min] | 1 | 1 | 1 | 1 | 1 | 30 | 20 | 1 | 1 | 30 |
| Evaluation | Removability of photoresist, | A | A | A | A | A | A | C | A | B | C |
| | anti-reflection film, residue | | | | | | | | | | |
| | Corrosion of copper, Ti, TiN, | A | A | A | A | A | A | A | B | A | A |
| | and silicon substrate | | | | | | | | | | |
| | Corrosion of SiOC-based | A | A | A | A | A | A | A | B | A | A |
| | interlayer insulating film | | | | | | | | | | |

| | | | Example/Comparative Example | | | | | |
|---|---|---|---|---|---|---|---|---|
| | | | Comparative Example | | | | | |
| | | | 5 | 6 | 7 | 8 | 9 | 10 |
| Solution No. | | | 10 | 11 | 12 | 13 | 14 | 15 |
| Composition | Quaternary ammonium | Tetramethylammonium | — | 10 | 22 | — | 18 | 5 |
| (wt %) | hydroxide | hydroxide | | | | | | |
| | | Tetraethylammonium | 20 | — | — | 20 | — | — |
| | | hydroxide | | | | | | |
| | Oxidizing agent | Hydrogen peroxide | — | — | 7 | 10 | 12 | — |
| | | Nitric acid | — | 11 | — | 5 | — | 2 |
| | Alkali metal hydroxide | Sodium hydroxide | 6 | — | — | — | 4 | — |
| | | Potassium hydroxide | — | 12 | — | — | — | 1 |
| | | Cesium hydroxide | — | — | — | 5 | — | — |
| | Alkanolamine | Monoethanolamine | — | — | 15 | — | 55 | 8 |
| | | Triethanolamine | 25 | 10 | — | — | — | — |
| | Water | | 49 | 57 | 56 | 60 | 11 | 84 |
| | Water-soluble organic | Dimethylsulfoxide | — | — | — | — | — | — |
| | solvent | | | | | | | |
| | Corrosion inhibitor | 1,2,3,-Benzotriazole | — | — | — | — | — | — |
| | Corrosion inhibitor | Catechol | — | — | — | — | — | — |
| | Fluorine-containing | Ammonium fluoride | — | — | — | — | — | — |
| | compound | | | | | | | |
| | Surfactant | Sodium | — | — | — | — | — | — |
| | | dodecylbenzenesulfonate | | | | | | |

| | | | | | | | |
|---|---|---|---|---|---|---|---|
| Treatment | pH | 13.5 | 14.5 | 10.9 | 12.1 | 13.8 | 10.5 |
| conditions | Temperature [° C.] | 20 | 20 | 60 | 60 | 20 | 70 |
| | Time [min] | 1 | 1 | 30 | 30 | 1 | 30 |
| Evaluation | Removability of photoresist, | A | A | C | B | A | C |
| | anti-reflection film, residue | | | | | | |
| | Corrosion of copper, Ti, TiN, | B | C | A | A | B | A |
| | and silicon substrate | | | | | | |
| | Corrosion of SiOC-based | A | C | A | A | B | A |
| | interlayer insulating film | | | | | | |

What is claimed is:

1. A stripping liquid for a semiconductor device, the stripping liquid comprising an aqueous solution comprising a quaternary ammonium hydroxide, an oxidizing agent, an alkanolamine, and an alkali metal hydroxide.

2. The stripping liquid according to claim 1, wherein the quaternary ammonium hydroxide is at least one compound selected from the group consisting of tetramethylammonium hydroxide, tetraethylammonium hydroxide, trimethylhydroxyethylammonium hydroxide, methyltri(hydroxyethyl)ammonium hydroxide, and tetra(hydroxyethyl)ammonium hydroxide.

3. The stripping liquid according to claim 1, wherein the quaternary ammonium hydroxide is tetramethylammonium hydroxide and/or tetraethylammonium hydroxide.

4. The stripping liquid according to claim 1, wherein the quaternary ammonium hydroxide has a content, relative to the total weight of the stripping liquid, of 0.01 to 50 wt %.

5. The stripping liquid according to claim 1, wherein the oxidizing agent is at least one compound selected from the group consisting of hydrogen peroxide, nitric acid and salts thereof, and ammonium persulfate, periodate, perbromate, perchlorate, iodate, bromate, and chlorate.

6. The stripping liquid according to claim 1, wherein the oxidizing agent is hydrogen peroxide and/or nitric acid.

7. The stripping liquid according to claim 1, wherein the oxidizing agent has a content, relative to the total weight of the stripping liquid, of 0.01 to 20 wt %.

8. The stripping liquid according to claim 1, wherein the alkanolamine is represented by Formula (1)
R¹₃₋ₙN(CₘH₂ₘ(OH))ₙ (1)
(in Formula (1), R¹ denotes a hydrogen atom or an alkyl group having 1 to 4 carbons, m denotes an integer of 2 to 4, and n denotes an integer of 1 to 3).

9. The stripping liquid according to claim 1, wherein the alkanolamine is at least one compound selected from the group consisting of monoethanolamine, diethanolamine, triethanolamine, propanolamine, dipropanolamine, tripropanolamine, isopropanolamine, diisopropanolamine, triisopropanolamine, butanolamine, N-methylethanolamine, N-methyldiethanolamine, N,N-dimethylaminoethanol, N-ethylethanolamine, N-ethyidiethanolamine, N,N-diethylethanolamine, N-n-butylethanolamine, and N,N-di-n-butylethanolamine.

10. The stripping liquid according to claim 1, wherein the alkanolamine is at least one compound selected from the group consisting of monoethanolamine, diethanolamine, and triethanolamine.

11. The stripping liquid according to claim 1, wherein the alkanolamine has a content, relative to the total weight of the stripping liquid, of 0.01 to 50 wt %.

12. The stripping liquid according to claim 1, wherein the alkali metal hydroxide is at least one compound selected from the group consisting of lithium hydroxide, sodium hydroxide, potassium hydroxide, rubidium hydroxide, and cesium hydroxide.

13. The stripping liquid according to claim 1, wherein the alkali metal hydroxide is at least one compound selected from the group consisting of sodium hydroxide, potassium hydroxide, and cesium hydroxide.

14. The stripping liquid according to claim 1, wherein the alkali metal hydroxide has a content, relative to the total weight of the stripping liquid, of 0.01 to 10 wt %.

15. The stripping liquid according to claim 1, wherein it has a pH of 7 to 15.

16. The stripping liquid according to claim 1, wherein it further comprises a compound selected from the group consisting of a water-soluble organic solvent, a corrosion inhibitor, a fluorine-containing compound, and a surfactant.

17. A stripping method comprising:
a stripping liquid preparation step of preparing the stripping liquid according to claim 1; and
a stripping step of removing at least one deposit selected from the group consisting of a photoresist, an anti-reflection film, and an etching residue by means of the stripping liquid obtained in the stripping liquid preparation step.

18. The stripping method according to claim 17, wherein the anti-reflection film is an organosiloxane-based compound.
